(19) United States
(12) Patent Application Publication
(10) Pub. No.: US 2026/0221397 A1
(43) Pub. Date: Jul. 30, 2026

(54) REACTOR DESIGN OPTIMIZATION WITH DC BIAS PULSING TO PEDESTAL

(71) Applicant: Lam Research Corporation, Fremont, CA (US)

(72) Inventors: Shaun Tyler Smith, Portland, OR (US); Lee Chen, Cedar Creek, TX (US); Neil M.P. Benjamin, Palo Alto, CA (US)

(21) Appl. No.: 19/145,790

(22) PCT Filed: Jan. 2, 2024
(86) PCT No.: PCT/US2024/010085

§ 371 Date: Jul. 3, 2025

Related U.S. Application Data
(60) Provisional application No. 63/437,311, filed on Jan. 5, 2023.

(51) Int. Cl. H01J 37/32; H10P 72/00

(52) U.S. Cl. CPC H01J 37/32697; H01J 37/32091; H01J 37/321; H01J 37/32146; H01J 37/32366; H01J 37/32568; H01J 37/32715; H10P 72/0421; H01J 2237/0044; H01J 2237/3341

(57) ABSTRACT

A plasma processing system, including a main plasma chamber configured for generating a main plasma, wherein the plasma chamber includes a bottom electrode located within an electrostatic chuck (ESC). The system including a direct current (DC) generator providing a pulsed DC bias signal to the bottom electrode over a plurality of cycles. The plasma processing system including a neutralization source that is external to the main plasma chamber, wherein the neutralization source is configured for providing a neutralization current into the main plasma chamber, wherein the neutralization current is electrically coupled to the main plasma.

### TECHNICAL FIELD

The present embodiments relate to semiconductor fabrication, and more specifically to systems and methods for minimizing the neutralization time in a plasma processing system with DC bias pulsing to the pedestal by effectively maximizing the effective counter electrode area as seen by the plasma in order to implement high duty cycle operation of the DC bias signal while maintaining a monoenergetic IEDF or ion population.

### BACKGROUND OF THE DISCLOSURE

Many modern semiconductor chip fabrication processes such as plasma etching processes are performed within a plasma processing chamber in which a substrate, e.g., wafer, is supported on an electrostatic chuck (ESC). In plasma etching processes, the wafer is exposed to a plasma generated within a plasma processing volume. Plasma contains various types of radicals, electrons, as well as positive and negative ions. The chemical reactions of the various radicals, electrons, positive ions, and negative ions are used to etch features, surfaces and materials of a wafer.

For example, when a process gas is supplied into the plasma processing chamber, a radio frequency (RF) signal provides power and is applied to at least one of the electrodes of the plasma processing chamber to form an electric field between the electrodes. The process gas is turned into plasma by the RF signal, thereby performing plasma etching on a predetermined layer disposed on the wafer. A bias signal may be applied in order to control ion distribution and/or ion population. However, effectiveness of the bias signal may be limited by wafer charging (e.g., by positive ions) and its discharge (e.g., electron current to the chamber wall being limited by bohm flux) thereby leading to undesirable ion energy distributions. What is desired is means for effectively increasing the wafer discharge.

It is in this context that embodiments of the disclosure arise.

### SUMMARY

The present embodiments relate to methods and apparatus for minimizing the neutralization time in a plasma processing system utilizing DC bias pulsing to the pedestal by effectively maximizing the effective counter electrode area as seen by the plasma. In that manner, effectively maximizing the counter electrode area enables high performance DC bias signal pulsing that achieves a monoenergetic ion energy distribution function (IEDF) or ion population. Several inventive embodiments of the present disclosure are described below.

Embodiments of the present disclosure provide for a plasma processing system. The plasma processing system includes a main plasma chamber configured for generating a main plasma. The plasma chamber includes a bottom electrode located within an electrostatic chuck (ESC). The plasma processing system includes a direct current (DC) generator providing a pulsed DC bias signal to the bottom electrode over a plurality of cycles. The plasma processing system includes a neutralization source that is external to the main plasma chamber. The neutralization source is configured for providing a neutralization current into the main plasma chamber. The neutralization current is electrically coupled to the main plasma.

Other embodiments of the present disclosure provide for another plasma processing system that is configured for using two plasmas. The plasma processing system using two plasmas includes a main plasma chamber configured for generating a main plasma, wherein the main plasma chamber includes a bottom electrode located within an electrostatic chuck (ESC). The plasma processing system using two plasmas includes a direct current (DC) generator providing a pulsed DC bias signal to the bottom electrode over a plurality of cycles. The pulsed DC bias signal has an ON period and an OFF period in each cycle of the plurality of cycles. The plasma processing system using two plasmas includes a secondary plasma chamber that is external to the main plasma chamber, wherein the secondary plasma chamber is configured for generating a secondary plasma that is more negatively charged than the main plasma. In some embodiments, the space potential (e.g., negative charge) on the secondary plasma could be time varying, such as in some synchronized form with the pulsed DC bias signal. The plasma processing system using two plasmas includes a pump for delivering the secondary plasma into the main plasma chamber in order to provide a neutralization current that is electrically coupled to the main plasma.

Still other embodiments of the present disclosure provide for a method for plasma processing. The method includes generating a main plasma in a main plasma chamber, wherein the main plasma chamber includes a bottom electrode located within an electrostatic chuck (ESC). The method includes generating a pulsed DC bias signal that is delivered to the bottom electrode over a plurality of cycles. The method includes providing a neutralization current that is generated from a neutralization source that is external to the main plasma chamber. The neutralization current is electrically coupled to the main plasma

These and other advantages will be appreciated by those skilled in the art upon reading the entire specification and the claims.

### BRIEF DESCRIPTION OF THE DRAWINGS

The embodiments may best be understood by reference to the following description taken in conjunction with the accompanying drawings.

FIG. 1 illustrates an embodiment of a capacitive coupled plasma (CCP) processing system utilized for etching operations, in accordance with an implementation of the disclosure.

FIG. 2 illustrates a plasma processing system having a large wall area to increase the electron current discharging to the chamber wall thereby increasing the discharge and/or neutralization of positive ions on the surface of the wafer, in accordance with one embodiment of the present disclosure.

FIG. 3A illustrates a plasma processing system including chamber wall features that increase the effective area of a chamber wall for purposes of increasing the discharge and/or neutralization of positive ions on the surface of the wafer, in accordance with one embodiment of the present disclosure.

FIGS. 3B, 3C-1, 3C-2, and 3D illustrate various configurations of chamber wall features, in accordance with embodiments of the present disclosure.

FIG. 4A illustrates a plasma processing system that includes an external neutralization source configured for providing a neutralization current to effectively discharge and/or neutralize positive ions on the surface of the wafer, in accordance with one embodiment of the present disclosure.

FIG. 4B illustrates a plasma processing system utilizing two plasmas that includes a secondary plasma provided by an externally coupled plasma source, in accordance with one embodiment of the present disclosure.

FIG. 4C illustrates a plasma processing system that includes an external neutralization source configured as an annular ring surrounding a main plasma chamber, wherein the neutralization source provides a neutralization current to effectively discharge and/or neutralize positive ions on the surface of the wafer, in accordance with one embodiment of the present disclosure.

FIG. 5 is a flow diagram illustrating a method for plasma processing configured for increasing the discharge and/or neutralization of positive ions on a surface of a wafer, in accordance with one embodiment of the present disclosure.

### DETAILED DESCRIPTION

Although the following detailed description contains many specific details for the purposes of illustration, anyone of ordinary skill in the art will appreciate that many variations and alterations to the following details are within the scope of the present disclosure. Accordingly, the aspects of the present disclosure described below are set forth without any loss of generality to, and without imposing limitations upon, the claims that follow this description.

Generally speaking, the various embodiments of the present disclosure describe methods and apparatus that provide for arbitrarily high duty cycle operations while maintaining a monoenergetic IEDF (e.g., ion population generated at approximately a desired energy level) for plasma processing systems providing DC pulsing applications. Generally, limitations to the maximum duty cycle of the DC bias signal are affected by wafer charging (e.g., by positive ions) during the ON period of cycles of the DC bias signal and wafer discharge during the OFF period of cycles of the DC bias signal. In particular, the rate of the discharge of positive ions from the surface of the wafer is limited by the available electron flux to the wafer during the pulse OFF time (i.e., OFF period of a cycle) of the DC bias signal. For purposes of illustration, a negative-DC square pulse can be applied to the wafer chuck electrode during the ON period. Ions swarm the wafer surface according to the Bohm current. The high-negative wafer surface potential instantaneously drives down the plasma potential (the ON period negative-DC square pulse period may be orders of magnitude longer than the RF period). It is this action that pushes electrons, in an excess amount, to the chamber wall surfaces, residing there as negative static charge. The surface negative static charge is “different” from the surface potential of the chamber walls, which is the instantaneous surface floating potential and is determined by, in part, the instantaneous plasma potential, electron temperature (assuming a single-temperature Maxwellian plasma), and the wall capacitance (inverse of the wall dielectric coating's thickness). Generally, a high-positive DC square pulse can be applied (i.e., switching from the negative-DC square pulse) during the “OFF period” of the pulsing scheme (e.g., DC bias signal). At the onset of the high-positive DC square pulse, the wafer surface potential follows pretty much the square pulse to a high-positive potential (i.e., due to capacitive coupling). Plasma electrons immediately swarm the wafer surface due the electron high mobility. This action immediately drives up the plasma potential (also known as “Boundary Driven Plasma Potential”). In general, such instantaneous artificial plasma potential is a few volts above the wafer surface potential according to the Global Model. Hence, plasma electrons (i.e., those of the Energetic Tail) still swarm and neutralize the wafer surface ions. The problem is that if the negative static charge on the chamber wall is not fully neutralized during the OFF period, that negative static charge will grow over several pulsing periods until an equilibrium is reached. The net effect when equilibrium is reached is that the narrow-IEDF ion-energy will be significantly lower than the negative-DC square pulse voltage level, which renders the DC pulsing useless. In embodiments, a countermeasure is to have an extremely asymmetric reactive ion chamber (RIE) chamber where the (e.g., capacitively) grounded chamber wall area is much larger than the wafer chuck area. Roughly, if a 90% duty cycle is targeted, the chamber wall area is roughly 10× of the wafer chuck area. The chamber wall surface incurs a negative charge (e.g., electrons) build-up as static charge (on an insulator surface) during the ON period; wherein the negative static charge (e.g., electrons) are not going to fly off during the OFF period. Generally, plasma ions (e.g., positive) are required to remove the negative static charge build-up on the chamber wall surface. Bohm current (or the current density) is a constant for the plasma. As such, the bigger the chamber wall area, the quicker the ion-current can neutralize the static negative charge build-up on the chamber wall surface. In other embodiments, because it takes an enormous force to rip off the static charge from the chamber wall surface (e.g., atomic scale for a given binding potential), removal of the static charge may be achieved on the quantum level—i.e., due to the Photoelectric Effect. In one embodiment, a high intensity pulse lamp may be employed during the OFF period such that static surface electrons may come off as photoelectrons.

Embodiments of the present disclosure overcome this limitation of the maximum duty cycle of the DC bias signal to enable previously unavailable process regimes. In particular, embodiments of the present disclosure provide for minimizing the neutralization time in high performance DC pulsed bias plasma processing systems by effectively maximizing the counter electrode area in order to achieve and/or maintain a monoenergetic IEDF.

Advantages of the various embodiments include methods and apparatus configured for providing arbitrarily high duty cycle operations of the pulsed DC bias signal while maintaining a monoenergetic IEDF (e.g., ion population at a desired energy level) for plasma processing systems configured for DC pulsing applications. In embodiments, the duty cycle of the pulsed DC bias signal (percentage of the ON period in one cycle) is greater than 40 percent, or greater than 50 percent, or greater than 60 percent, or greater than 70 percent, or greater than 80 percent, or greater than 90 percent.

With the above general understanding of the various embodiments, example details of the embodiments will now be described with reference to the various drawings. Similarly numbered elements and/or components in one or more figures are intended to generally have the same configuration and/or functionality. Further, figures may not be drawn to scale but are intended to illustrate and emphasize novel concepts. It will be apparent, that the present embodiments may be practiced without some or all of these specific details. In other instances, well-known process operations have not been described in detail in order not to unnecessarily obscure the present embodiments.

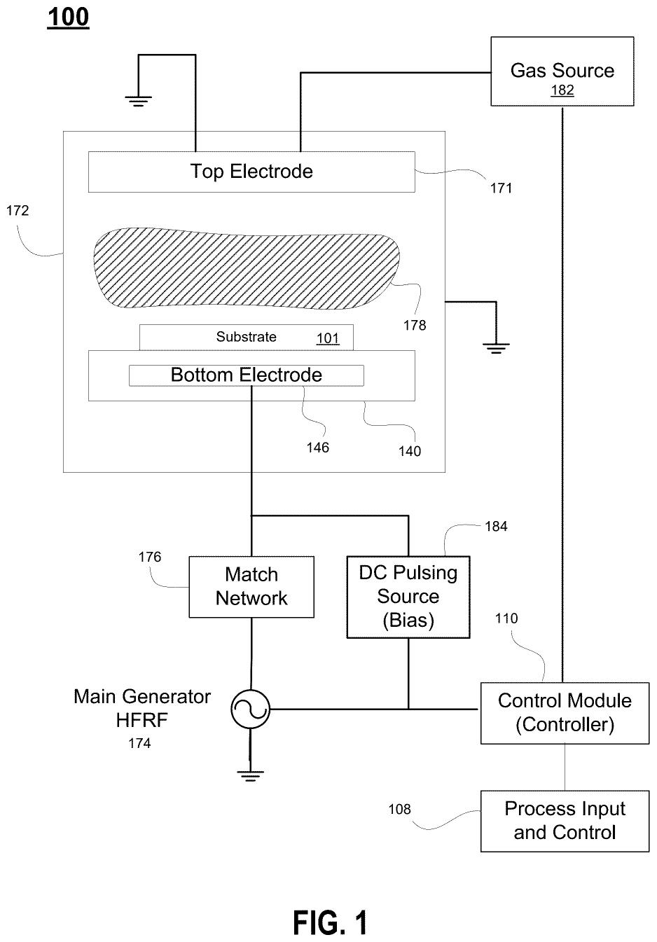

FIG. 1 illustrates an exemplary substrate processing or reactor system 100, which may be used to process a wafer, to include etching features within masked substrates, such as when performing high aspect ratio dielectric etch, and/or depositing or forming films over the wafer, in accordance with one embodiment of the present disclosure. For example, the substrate processing system 100 is used to process a substrate or wafer 101, such as by performing plasma processing of the wafer 101, and may be modified depending on design to generate plasmas through various methods, including capacitively coupled plasmas (CCPs), inductively coupled plasmas (ICPs) including inductive coils used for exciting a plasma instead of an electrode, etc. For brevity and clarity, embodiments of the present disclosure configured for minimizing the neutralization time in processing operations utilizing DC bias pulsing to the pedestal are described as being implemented within a CCP processing system, although it is understood that other embodiments are well suited for implementation within other plasma processing systems (e.g., ICPs, etc.). It is also understood that other configurations of plasma processing systems may utilize various combinations of high frequency RF power, low frequency RF power, and/or DC power for providing power, wherein each power source may be pulsed or non-pulsed.

As shown, the system 100 includes a plasma chamber 172, which is a CCP chamber. The plasma chamber 172 includes a substrate support or pedestal 140, such as an electrostatic chuck (ESC), or magnetic chuck. A bottom electrode 146 may be embedded within the pedestal 140. A substrate 101 may be placed on the pedestal 140 for processing, wherein the substrate 101 is processed to make one or more semiconductor chips. Facing the pedestal is a top electrode 171 of the plasma chamber 172. As shown, the top electrode may be coupled to ground to facilitate a return of RF energy. In other embodiments, the top electrode 171 may be coupled to an RF power supply (e.g., supplying high frequency power, etc.). Between the top electrode 171 and the bottom electrode 146 is a gap forming a processing volume within which a plasma 178 may be formed. A gas pump (not shown) may be used to remove gases and byproducts from the plasma chamber 172.

A control module 110 is configured to operate the substrate processing system 100 by executing process input and control 108. In one embodiment, the control module 110 is connected to the generators (e.g., main RF generator 174, DC source generator 184), to the gas source 182, and to other components. The controller 110 includes a processor, memory, software logic, hardware logic and input and output subsystems from communicating with, monitoring and controlling the plasma processing system 100. Depending on the processing being performed, the control module 110 controls the delivery of process gases delivered from the gas source 182 to achieve a designed processing condition. The chosen gases are then distributed in a space volume defined between the top electrode 171 and the wafer 101 resting over pedestal 140. As an example of plasma formation, after providing one or more signals (e.g., RF, DC, etc.) to the bottom electrode 146 and injecting process gas(es) into the plasma process chamber 172, plasma 178 is then formed between the top electrode 171 and the pedestal 140. The plasma 178 can be used to etch the surface of the wafer 101. In particular, the process input and control 108 may include process recipes, such as power levels, timing parameters, process gases, mechanical movement of the wafer 101, etc., such as to etch features in stack structures of a wafer 101 and/or deposit or form films over the wafer 101. In particular, control module 110 may be configured to operate the substrate processing system 100 to perform etching of high aspect ratio features in a stack of a masked substrate, to include tuning the composition of the etching chemistry in various cycling stages, and pulsing parameters of an RF power supply 174 (e.g., source generator) and a pulsed DC bias power supply 184.

A source RF power supply 174 (e.g., source power generator) is coupled to an impedance match network 176 that is further coupled to the plasma chamber 172, wherein the match network enables dynamic tuning of power provided to the bottom electrode 146 by matching impedances between the load (e.g., plasma chamber and any connecting cabling) and a source (e.g., source RF power supply and any connecting cabling). In particular, the impedance match network 176 is coupled to the bottom electrode 146 located within the pedestal 140 (e.g., ESC). The source RF power supply 174 is used typically to generate the plasma 178 using the process gases delivered from the gas source 182. For example, the source RF power supply 174 may be a high frequency (HF) RF generator providing power via sinusoidal or alternating current (AC) signals (i.e., varying voltage signals in sinusoidal form), which may be further configured to produce high frequencies ranging from and including 13 megahertz (MHz) to 120 MHz. For example, the high frequency is a baseline frequency of 13.56 MHz or 27 MHz or 40 MHz or 60 MHz or 100 MHz. In one embodiment, the source RF power supply 174 provides pulsed RF power.

The DC power source 184 provides a pulsed DC bias signal. In particular, a constant voltage DC signal may be pulsed to provide the pulsed DC bias signal. The pulsed bias voltage is applied to the bottom electrode for purposes of attracting ions to the wafer 101 located on the pedestal 140 and/or to control ion distribution. In one embodiment, the pulsed DC bias signal is provided to the match network 176, and in another embodiment, the pulsed DC bias signal bypasses the impedance match network 176. In either case, the RF signal from the source RF power supply 174 is combined with the pulsed DC bias signal from the DC power source 184 to drive the bottom electrode 146 in order to generate the plasma 178.

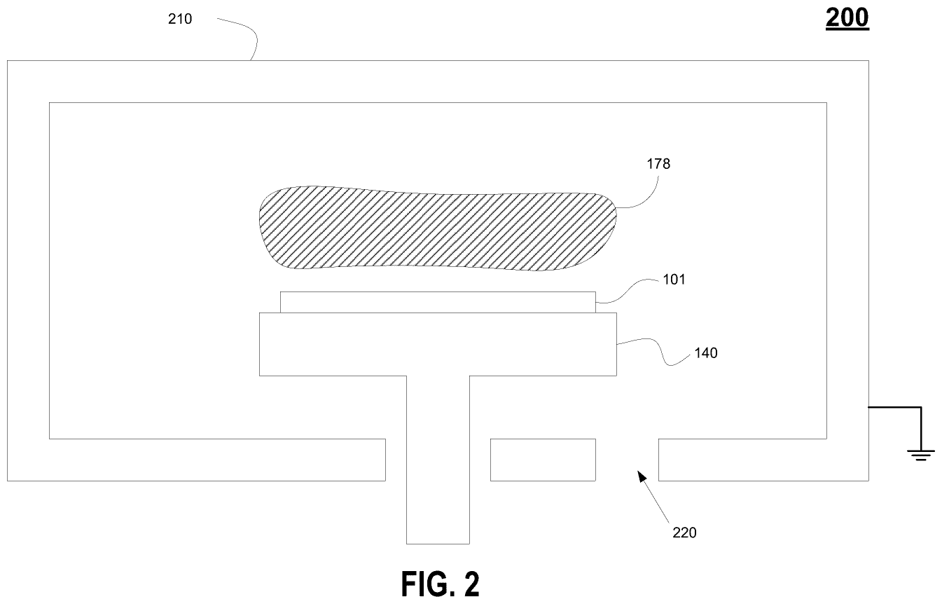

FIG. 2 illustrates a plasma processing system 200 having a large wall area to increase the electron current discharging to the chamber wall, thereby increasing the discharge and/or neutralization of positive ions on the surface of the wafer, in accordance with one embodiment of the present disclosure. As previously described, the plasma processing system 200 utilizes DC bias pulsing to the pedestal 140 to achieve a monoenergetic ion excitation of ions at the wafer surface (e.g., controllable monoenergetic IEDF at desired energy levels).

In particular, plasma processing system 200 includes, in part, a chamber 210 configured for generating a plasma 178, pedestal 140 configured for supporting a wafer 101, and a pump port 220 configured for exhausting gases and/or byproducts from the chamber 210. Plasma processing system 200 may be similar to plasma processing system 100 of FIG. 1 such that both systems are configured for plasma processing (e.g., generating plasma using a CCP chamber, ICP chamber, etc.), wherein like components are represented by like reference numerals. However, plasma processing system 200 includes chamber 210, with respect to a surface of the wafer 101, that is larger than the chamber 172 of FIG. 1.

In particular, without wishing to be bound by theory or mechanism of action, it is believed that control of IEDF at defined energy levels is limited by a maximum duty cycle of the pulsed DC bias signal, wherein the maximum duty cycle is correlated to the area ratio between the wafer 101 and the chamber 210. Steady state operation of the pulsed DC bias signal to generate a monoenergetic ion population requires that the net charge at the wafer does not evolve over time despite the presence of a DC component present in the bias drive. This requires that the ion flux is approximately or exactly balanced by the electron flux at the wafer surface for each pulse cycle of the DC bias signal. For example, discharge of the positive ions on the surface of the wafer through a bohm flux or current (flow of positive ions) to the wall occurs during the OFF period of each cycle of the DC bias signal. In particular, the area ratio indicates a level of asymmetry between the bottom electrode and the top electrode, or asymmetry between the surface area of the wafer 101 and the surface area of the chamber 210. More specifically, a desired increase in the maximum duty cycle can be achieved by increasing the asymmetry between wafer and the chamber, and more specifically by increasing the surface area of the chamber 210 for a given wafer size. That is, the chamber 210 is made purposefully large with respect to a surface of the wafer 101 (e.g., greater than 10 times) to facilitate rapid discharging of negative static charge on the chamber walls during an OFF period of the pulsed DC bias signal, wherein negative static charging of the chamber walls (i.e., negative static charge build-up on walls) occurs during the previous ON period of the pulsed DC bias signal. In that manner, negative static charges built-up during a previous ON period are “neutralized” during the subsequent OFF period. For example, the area ratio between the surface area of the chamber 210 and a wafer surface may range from greater than 2-10 to 1, including area ratios that are greater than 2 to 1, or greater than 3 to 1, or greater than 4 to 1, or greater than 5 to 1, or greater than 6 to 1, or greater than 7 to 1, or greater than 10 to 1. In particular, an increase in the area ratio provides for an increase in the bohm current from the plasma 178 (e.g., especially at the wafer surface) to the walls of the chamber 210 (e.g., providing a larger grounded electrode), thereby minimizing the neutralization time of positive ions at the surface of the wafer (e.g., minimizing the OFF period of each cycle of the pulsed DC bias signal), which further corresponds to an increase in the duty cycle of the pulsed DC bias signal.

In general, the Bohm current to the wall discharges the negative (electron) static charges that are built-up during the previous ON period. In addition, during the subsequent OFF period, the wafer chuck can be swung to some positive voltage, and as such plasma electrons will swarm the wafer surface thereby neutralizing the positive ions that accumulated on the wafer surface during the previous ON period. This process is prompt and readily available. In particular, the plasma electrons swarming the wafer surface are from the energetic tail population, which can easily overcome the wafer sheath and reach the wafer surface to neutralize the earlier-accumulated positive ions. This electron population is tiny compared to the Maxwellian bulk; however, even in a collisionless regime, and especially in a collisionless regime where electron-electron thermalization collision and electron-neutral thermalization collision are not considered, the emptied-out Tail Population will be replenished with electrons within a fraction of nanosecond, continuing the electron-flux to overcome the wafer sheath. In another words, the Tail Population is practically unchanged.

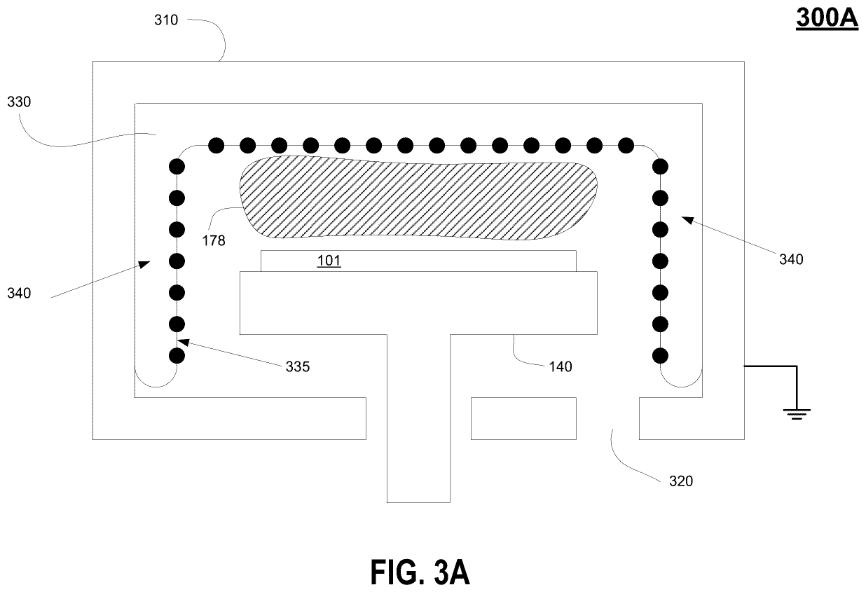

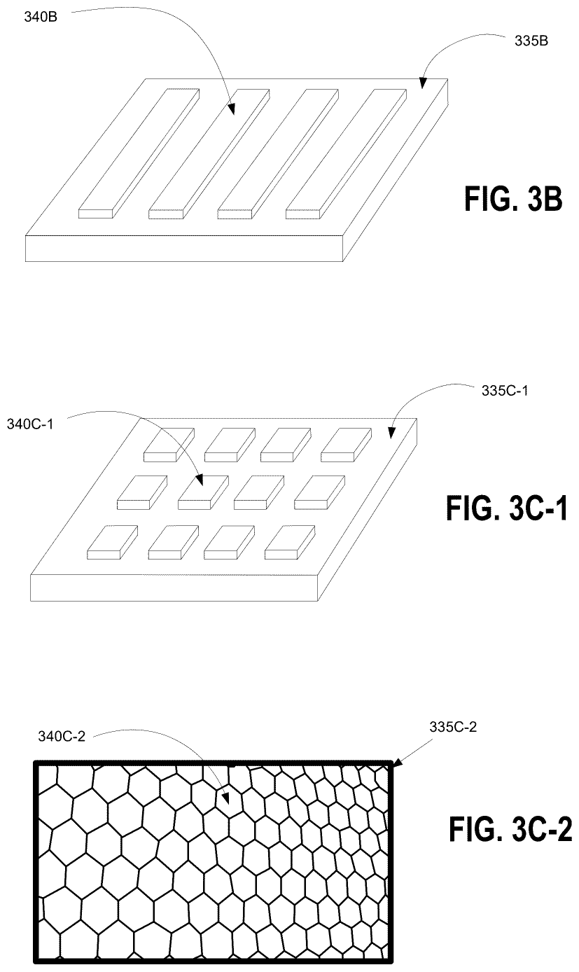

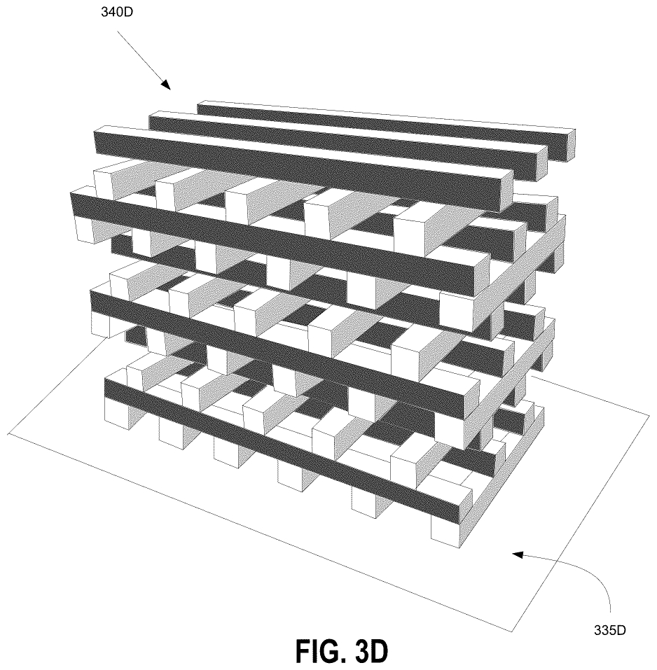

FIG. 3A illustrates a plasma processing system 300A including chamber wall features that increase the effective area of a chamber wall for purposes of increasing the discharge and/or neutralization of positive ions on the surface of the wafer, in accordance with one embodiment of the present disclosure. As previously described, the plasma processing system 300A utilizes DC bias pulsing to the pedestal to achieve a monoenergetic ion excitation of ions at the wafer surface (e.g., controllable monoenergetic IEDF at desired energy levels).

In particular, plasma processing system 300A includes, in part, a chamber 310 configured for generating a plasma 178, pedestal 140 configured for supporting a wafer 101, and a pump port 320 configured for exhausting gases and/or byproducts from the chamber 310. Plasma processing system 300A may be similar to plasma processing system 100 of FIG. 1 such that both systems are configured for plasma processing (e.g., generating plasma using a CCP chamber, ICP chamber, etc.), wherein like components are represented by like reference numerals. In particular, the volume of vacuum chamber 310 may be similar to the chamber 172 of FIG. 1, wherein both chambers are normally sized (i.e., with respect to a surface area of a wafer 101).

As in the various other embodiments of the present disclosure described throughout the specification, plasma processing system 300A is configured to increase the rate of discharge of positive ions from the surface of the wafer by increasing the available electron flux to the wafer (e.g., plasma electrons from the Tail population can easily swarm the wafer surface) and also increase the ion flux to the wall of the chamber during the pulse OFF period of a cycle of the corresponding pulsed DC bias signal. In that manner, the neutralization time of ions is minimized (i.e., neutralization of wafer surface ion is practically instantaneous, and the neutralization of the static negative charge built-up on the chamber wall surface is sped up by the incoming ions due to the increased ion flux to the wall) in order to achieve arbitrarily high duty cycle operations of the pulsed DC bias signal while maintaining a monoenergetic IEDF for plasma processing systems providing DC pulsing applications.

As previously described, a desired increase in the maximum duty cycle of the pulsed DC bias signal can be achieved by increasing the asymmetry between wafer 101 and the chamber 310, and more specifically by increasing the effective surface area of the chamber 310 for a given wafer size (i.e., in order to increase the area ratio). As such, an increase in the asymmetry between the surface area of the wafer 101 and the surface area of the chamber 310 (e.g., increased area of the grounded electrode) is achieved.

As shown in FIG. 3A, to achieve an increase in asymmetry, the effective surface area of the surface 335 of the chamber 310 can be increased without necessarily increasing the volume of the chamber 310, in one embodiment. For example, an interior layer 330 may be included that is adjacent to the walls of chamber 310, wherein the interior layer 330 may include a surface 335 that is facing the plasma 178. In other embodiments, surface 335 corresponds to the surface of the walls of chamber 310, such that no interior layer is introduced. In particular, surface 335 includes a plurality of features 340 to effectively increase the surface area (i.e., in comparison with a surface that does not include features) within chamber 310 that faces and/or is exposed to plasma 178.

The plurality of features 350 may be configured as various shapes and situated in various configurations in relation to surface 355 order to increase the effective surface area that is exposed to plasma of the surface 335. In one embodiment, at least one dimension of each feature in the plurality of features 340 is approximately on the order of a Debye length in order for penetration of the plasma into areas surrounding the plurality of features 340 (i.e., exposing the features to the plasma to increase the effective surface area). For example, the plurality of features may extend above a planar surface (e.g., of a corresponding region) associated with the surface 335, or the features may extend below the planar surface, or the features may be recessed within the planar surface, etc. For example, FIGS. 3B, 3C-1, 3C-2, and 3D illustrate various configurations of surface features, in accordance with embodiments of the present disclosure.

In particular, FIG. 3B illustrates a surface 335B (e.g., of an interior layer or of a wall of a chamber) that includes an exemplary plurality of features 340B configured as a one dimensional (1D) grating. FIG. 3C-1 illustrates a surface 335C-1 (e.g., of an interior layer or of a wall of a chamber) that includes an exemplary plurality of features 340C-1 configured as a two dimensional (2D) grating or extrusion. More particularly, the plurality of features 340C-1 may extend from surface 335C-1, or may be recessed within surface 335C-1 (i.e., go in or out from surface 335C-1). FIG. 3C-2 illustrates a surface 335C-2 that includes another exemplary plurality of features 340C-2 also configured as a 2D grating or extrusion, wherein the features may be configured as hollow extrusions, such as in the form of a honeycomb that extends outwards from the surface 335C-2 or extends inwards from the surface 335C-2 (i.e., inverse honeycomb). Also, FIG. 3D illustrates a surface 335D (e.g., of an interior layer or of a wall of a chamber) that includes an exemplary plurality of features 340D configured in three dimensions (3D). As shown, the plurality of features 340D may be configured as a “log pile” structure, or as a yablonovite structure, or any suitable 3D structure.

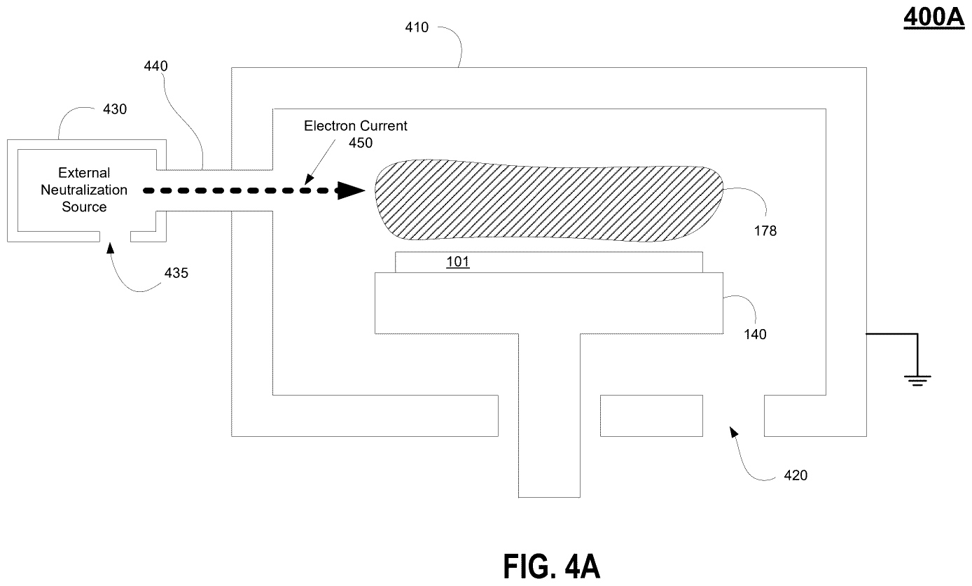

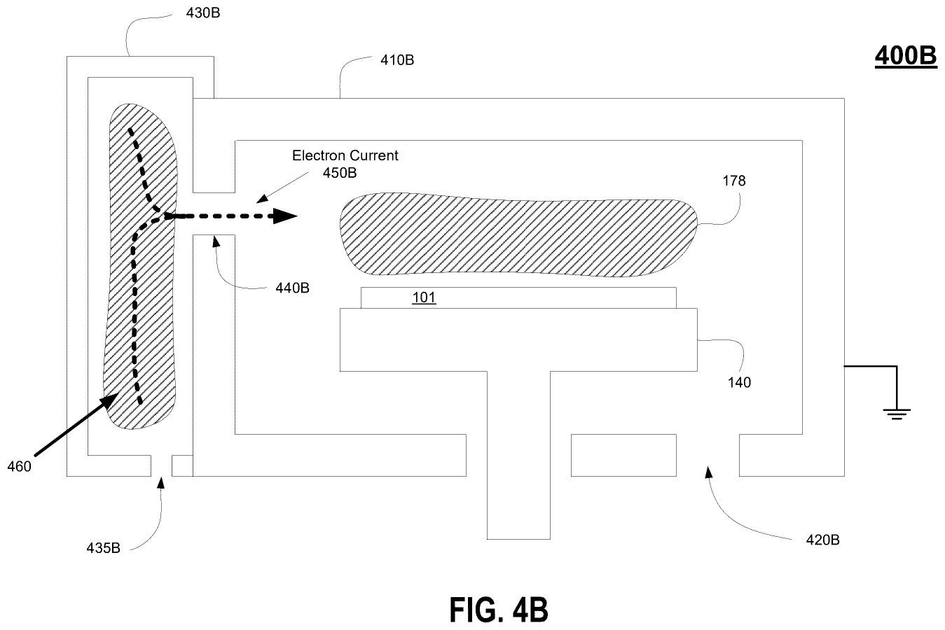

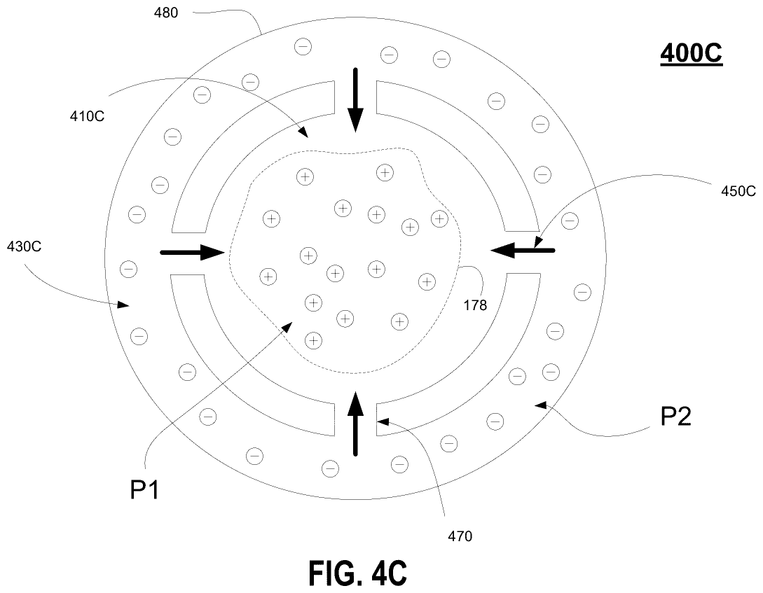

FIG. 4A illustrates a plasma processing system 400A that includes an external neutralization source 430 configured for providing a neutralization current to effectively discharge and/or neutralize positive ions on the surface of the wafer, in accordance with one embodiment of the present disclosure. The external neutralization source 430 effectively increases the area ratio between the surface of the wafer and the walls of the chamber 410 by introducing electrons into the volume of the chamber 410. As previously described, the plasma processing system 400A utilizes DC bias pulsing to the pedestal 140 to achieve a monoenergetic ion excitation of ions at the wafer surface (e.g., controllable monoenergetic IEDF at desired energy levels).

In particular, plasma processing system 400A includes, in part, a main chamber 410, pedestal 140 configured for supporting a wafer 101, and a pump port 420 configured for exhausting gases and/or byproducts from the main chamber 410. For example, main chamber 410 may include a bottom electrode within the pedestal 140 or ESC for receiving a high frequency RF signal used for generating a plasma 178. A DC generator may provide the pulsed DC bias signal to the bottom electrode over a plurality of cycles, wherein the pulsed DC bias signal has an ON period and an OFF period in each cycle of a plurality of cycles. Plasma processing system 400A may be similar to plasma processing system 100 of FIG. 1 such that both systems are configured for plasma processing (e.g., generating plasma using a CCP chamber, ICP chamber, etc.), wherein like components are represented by like reference numerals. However, plasma processing system 400A includes a neutralization source 430 that is external to the main chamber 410. The neutralization source 430 may include a pump port 435 configured to provide for pumping of electrons (e.g., pumping the electron current 450) generated by the neutralization source 430 through channel 440 into the main chamber 410.

As in the various other embodiments of the present disclosure described throughout the specification, plasma processing system 400A is configured to increase the rate of discharge of positive ions from the surface of the wafer by increasing the available electron flux to the wafer and correspondingly increasing the ion flux to the wall of the chamber during the pulse OFF period of a cycle of the corresponding pulsed DC bias signal. In particular, ion flux to any surface in thermal plasma (which is isotropic) is pegged by the Bohm flux, which is primarily driven by the Maxwellian electron temperature. Unless a sizable energetic electron flux is intentionally directed towards the surfaces, upon which the thermal plasma Bohm Criteria is modified, the thermal plasma Bohm flux cannot be altered. Ion Bohm flux is fundamentally determined by the thermal electron flux entering the Presheath. In the Global Model, one way to alter the thermal electron flux entering the Presheath is to alter the thermal electron temperature (e.g., for a given plasma density). If a sizable (i.e., as compared to the Maxwellian bulk) energetic electron flux (e.g., energy at and above that of the Tail Population) is intentionally directed towards the wall: then the Bohm Criteria becomes a Modified Bohm Criteria (i.e., because the Sheath Poisson's Equation is rewritten), and the ion Bohm flux can then truly be increased. As such, the overall electron flux (to the wafer and/or the main plasma chamber) during the OFF period can be significantly increased, thereby enabling a greater than 90 percent duty cycle of the DC bias signal.

In that manner, the neutralization time of ions is minimized in order to achieve arbitrarily high duty cycle operations of the pulsed DC bias signal while maintaining a monoenergetic IEDF for plasma processing systems providing DC pulsing applications. In particular, the electron flux to the wafer and/or the main plasma chamber is increased by introducing electrons into the volume of chamber 410 via the neutralization source 430. For example, the introduction of electrons vastly increases the electron flux into the main chamber during the OFF period, and neutralizes the rapid rise of the plasma potential of the main plasma chamber (e.g., achieve a practically non-rising main chamber plasma potential during the 10 percent neutralization OFF period by neutralizing the accumulation of negative-electron-static charge on the chamber wall surface during the previous ON period), in order to achieve a greater than 90 percent duty cycle of the pulsed DC bias signal.

In particular, the neutralization source 430 is external to the main chamber 410, and may be self-contained. The neutralization source 430 effectively increases the area ratio between the surface of the wafer and the walls of the chamber 410 by introducing electrons or neutralization charge into the volume of the chamber 410. That is, the neutralization source 430 is configured for generating electrons, and providing a neutralization current or electron current 450 into the main chamber 410. Also, the neutralization source 430 may physically increase the surface area of a combined surface that is exposed to the plasma 178 (e.g., walls of the chamber 410 and walls of the neutralization source 430. More particularly, the neutralization current 450 is electrically coupled to the main plasma 178. In one embodiment, the neutralization current 450 is continuously delivered into the main chamber 410 and correspondingly electrically coupled on a continuous basis to the plasma during the ON period and the OFF period of each cycle of the plurality of cycles of the pulsed DC bias signal. In some embodiments, the space potential (e.g., negative charge) on the secondary plasma could be time varying, such as in some synchronized form with the pulsed DC bias signal. In one embodiment, the neutralization current 450 is configured for neutralizing ions in a plurality of ions in the main plasma 178 during the OFF period in each cycle of a plurality of cycles of the pulsed DC bias signal.

In one embodiment, the neutralization source 430 is configured as an electron gun capable of generating electrons for the electron current 450 (e.g., by firing an electron beam into the main chamber 410). The electron gun may operate at conditions that are decoupled from the process conditions required by the main chamber 410. In that manner, the electron gun operates independently to enable generation of a large neutralization current. In one embodiment, the electron gun is external to the main chamber 410, and may provide electrons to an annular ring adjacent to main chamber 410, wherein multiple channels between the annular ring and the main chamber 410 allow for electrons to flow into the main chamber 410 from different points in the annular ring (e.g., at different and/or periodic angular points between 0 and 360 degrees of the annular ring). In another embodiment, the electron gun may be located within the main chamber 410 for purposes of generating electrons within the chamber for providing a neutralization charge to the main plasma 178.

In still other embodiments, the neutralization source 430 may utilize any suitable technique for generating electrons. For example, neutralization source 430 may be configured to generate electrons through thermal emission. Also, neutralization source 430 may be configured to generate electrons through a secondary plasma, as will be described in relation to FIG. 4B, below.

FIG. 4B illustrates a plasma processing system 400B utilizing two plasmas that includes a secondary plasma provided by an externally coupled plasma source, in accordance with one embodiment of the present disclosure. The external neutralization source 430B effectively increases the area ratio between the surface of the wafer and the walls of the chamber 410B by introducing electrons into the volume of the chamber 410B via a secondary plasma 460. As previously described, the plasma processing system 400B utilizes DC bias pulsing to the pedestal 140 to achieve a monoenergetic ion excitation of ions at the wafer surface (e.g., controllable monoenergetic IEDF at desired energy levels).

In particular, plasma processing system 400B includes, in part, a main plasma chamber 410B configured for generating a main plasma 178, pedestal 140 configured for supporting a wafer 101, and a pump port 420B configured for exhausting gases and/or byproducts from the main chamber 410. For example, main chamber 410B may include a bottom electrode within the pedestal 140 or ESC for receiving a high frequency RF signal used for generating plasma 178. A DC generator may provide the pulsed DC bias signal to the bottom electrode over a plurality of cycles, wherein the pulsed DC bias signal has an ON period and an OFF period in each cycle of a plurality of cycles. Plasma processing system 400B may be similar to plasma processing system 100 of FIG. 1 such that both systems are configured for plasma processing (e.g., generating plasma using a CCP chamber, ICP chamber, etc.), wherein like components are represented by like reference numerals. However, plasma processing system 400B includes a neutralization source 430B that is external to the main chamber 410. The neutralization source 430B may include a pump port 435B configured to provide for pumping of electrons (e.g., pumping the electron current 450B) generated by the neutralization source 430B through channel 440B into the main chamber 410B. That is, the plasma processing system 400B may include a pump that accesses the secondary plasma chamber of the neutralization source 430B in order to pump the secondary plasma 460 into the main plasma chamber 410B in order to provide a neutralization current that is electrically coupled to the main plasma.

As in the various other embodiments of the present disclosure described throughout the specification, plasma processing system 400B is configured to increase the rate of discharge of positive ions from the surface of the wafer by increasing the available electron flux to the wafer and correspondingly increasing the ion flux to the wall of the chamber during the pulse OFF period of a cycle of the corresponding pulsed DC bias signal. In that manner, the neutralization time of ions is minimized in order to achieve arbitrarily high duty cycle operations of the pulsed DC bias signal while maintaining a monoenergetic IEDF for plasma processing systems providing DC pulsing applications. In particular, the electron flux to the wafer is increased by introducing electrons into the volume of chamber 410B via a secondary plasma 460 generated by the neutralization source 430B.

In particular, the neutralization source 430B is external to the main chamber 410B, and is configured as a secondary plasma chamber. The neutralization source 430B effectively increases the area ratio between the surface of the wafer and the walls of the chamber 410B by introducing electrons or neutralization charge into the volume of the chamber 410B. That is, the neutralization source 430B is configured for generating electrons via a secondary plasma 460, and providing a neutralization current or electron current 450B into the main chamber 410B. In one embodiment, the secondary plasma 460 is more negatively charged than the main plasma 178. In that manner, electrons or neutralization charge can be introduced into the main chamber 410B in order to neutralize ions in the plasma 178, such as near the surface of the wafer 101. Also, the neutralization source 430B may physically increase the surface area of a combined surface that is exposed to the plasma 178 (e.g., walls of the chamber 410B and walls of the neutralization source 430B.

In particular, neutralization source 430B may generate plasma using RF power. In one embodiment, an RF power generator is shared between the main chamber 410B and the neutralization source 430B for purposes of generating the main plasma 178 and the secondary plasma 460. In another embodiment, the secondary plasma chamber of the neutralization source 430B includes an independent RF power generator. Further, the neutralization source 430B need only be electrically coupled to the main plasma 178, such that the neutralization source provides a neuralization current 450B that is electrically coupled to the main plasma 178. In one embodiment, the neutralization current 450B is continuously delivered into the main chamber 410B and correspondingly electrically coupled on a continuous basis to the plasma during the ON period and the OFF period of each cycle of the plurality of cycles of the pulsed DC bias signal. In one embodiment, the neutralization current 450B is configured for neutralizing ions in a plurality of ions in the main plasma 178 during the OFF period in each cycle of a plurality of cycles of the pulsed DC bias signal.

Further, the neutralization source 430B may operate at conditions that are decoupled from the process conditions required by the main chamber 410B. In that manner, the secondary plasma chamber of the neutralization source 430B operates independently to enable generation of a large neutralization current. For example, the secondary plasma chamber need not be at the same pressure as the main chamber 410B, and need not contain the same gases for plasma generation. In particular, the main plasma 178 may be generated from a first gas mixture under a first process condition in the main chamber 410B, whereas the secondary plasma 460 may be generated from a second gas mixture under a second process condition in the secondary plasma chamber of the neutralization source 430B.

FIG. 4C illustrates a plasma processing system 400C that includes an external neutralization source 430C configured as an annular ring 480 surrounding a main plasma chamber 410C. The neutralization source provides a neutralization current 450C to effectively discharge and/or neutralize positive ions in the main plasma 178 (e.g., ions on the surface of a wafer), in accordance with one embodiment of the present disclosure. The neutralization source may be representative of the neutralization sources in FIGS. 4A through 4C. In particular, neutralization source provides electrons to an annular ring 480 adjacent to main chamber 410C, wherein multiple channels 470 between the annular ring 480 and the main chamber 410C allow for electrons to flow into the main chamber 410 from different points in the annular ring 480 (e.g., at different and/or periodic angular points between 0 and 360 degrees of the annular ring). The neutralization source 430C is configured to generate electrons for supplying the neutralization current 450C. For example, the neutralization source 430C may be configured as an electron gun, or may be configured to generate electrons through thermal emission, or may be configured to generate electrons through a secondary plasma. As shown, the annular ring 480 may include a medium (e.g., secondary plasma) that includes a charge P1 that is more negatively charged than the charge P2 on the main plasma 178. In that manner, electrons or neutralization charge can be introduced into the main chamber 410C in order to neutralize ions in the plasma 178, such as near the surface of the wafer 101.

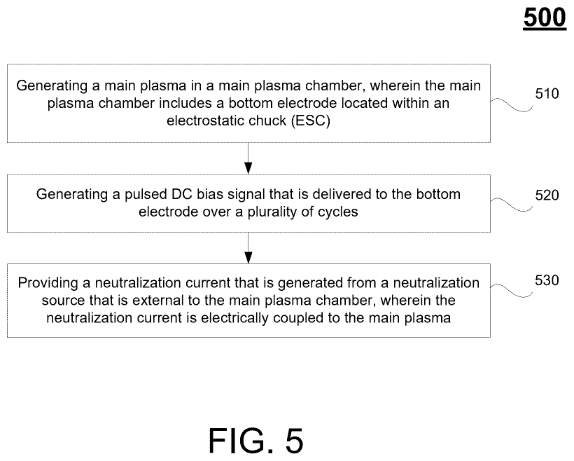

FIG. 5 is a flow diagram 500 illustrating a method for plasma processing configured for increasing the discharge and/or neutralization of positive ions on a surface of a wafer, in accordance with one embodiment of the present disclosure. The method of flow diagram 500 may be implemented to control processes in the plasma processing systems of FIGS. 1, 2, 3A, and 4A-4C, as well as for other plasma processing systems. For example, the method of flow diagram 500 may be stored in computer-readable form in memory accessible by control module 110 of FIG. 1 in order to perform the operations of flow diagram 500.

At 510, the method includes generating a main plasma in a main plasma chamber, wherein the main plasma chamber includes a bottom electrode located within an electrostatic chuck (ESC). The main plasma chamber may be configured as a CCP chamber, or an ICP chamber, or any type of chamber suitable for generating a plasma. As previously described, the plasma processing systems utilize DC bias pulsing to the pedestal to achieve a monoenergetic ion excitation of ions at the wafer surface (e.g., controllable monoenergetic IEDF at desired energy levels). In particular, at 520, the method includes generating a pulsed DC bias signal that is delivered to the bottom electrode over a plurality of cycles. In particular, the pulsed DC bias signal has an ON period and an OFF period in each cycle of a plurality of cycles of the bias signal.

As in the various other embodiments of the present disclosure described throughout the specification, flow diagram 500 as implemented within a corresponding plasma processing system is configured to increase the rate of discharge of positive ions from the surface of the wafer by increasing the available electron flux to the wafer and correspondingly increasing the ion flux to the wall of the chamber during the pulse OFF period of a cycle of the corresponding pulsed DC bias signal. In that manner, the neutralization time of ions is minimized in order to achieve arbitrarily high duty cycle operations of the pulsed DC bias signal while maintaining a monoenergetic IEDF for plasma processing systems providing DC pulsing applications.

At 530, the method includes providing a neutralization current that is generated from a neutralization source that is external to the main plasma chamber. The neutralization source effectively increases the area ratio between the surface of a corresponding wafer and the walls of a corresponding chamber used for generating the plasma by introducing electrons as the neutralization current into the volume of the chamber. In particular, the neutralization current is electrically coupled to the main plasma. In one embodiment, the neutralization current is continuously delivered into the main plasma during the ON period and the OFF period of each cycle of the plurality of cycles of the pulsed DC bias signal. Further, the neutralization current is configured for neutralizing ions in a plurality of ions of the main plasma (e.g., at a surface of a corresponding wafer) during the OFF period in the each cycle of the plurality of cycles.

For example, the neutralization source may be configured as an electron gun configured for generating electrons, wherein the method includes pumping the electrons (e.g., using a pump, or firing electrons into the chamber using the electron gun) into the main plasma chamber, in one embodiment. In another embodiment, the neutralization source may be a secondary plasma chamber that is configured for generating a secondary plasma. In one embodiment, the main plasma is generated from a first gas mixture under a first process condition in the main plasma chamber, and the secondary plasma is generated from a second gas mixture under a second process condition in the neutralization source. In one embodiment, the secondary plasma is more negatively charged than the main plasma in the main plasma chamber. In addition, the method includes pumping the electrons (e.g., using a pump) into the main plasma chamber, in one embodiment.

In embodiments, a program may include program code for controlling chamber components that are used for plasma processing, which may be implemented by control system 110 of FIG. 1. In some implementations, a controller is part of a system, which may be part of the above-described examples. Such systems can comprise semiconductor processing equipment, including a processing tool or tools, chamber or chambers, a platform or platforms for processing, and/or specific processing components (a substrate pedestal, a gas flow system, etc.). These systems may be integrated with electronics for controlling their operation before, during, and after processing of a semiconductor wafer or substrate. The controller, depending on the processing requirements and/or the type of system, may be programmed to control any of the processes disclosed herein, and process implemented for operating a plasma chamber. Program instructions may be instructions communicated to the controller in the form of various individual settings (or program files), defining operational parameters for carrying out a particular process on or for a semiconductor substrate or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” of all or a part of a fab host computer system, which can allow for remote access of the substrate processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, a plasma enhanced chemical vapor deposition (PECVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within their scope and equivalents of the claims.

1. A system, comprising:
a main plasma chamber configured for generating a main plasma, wherein the plasma chamber includes a bottom electrode located within an electrostatic chuck (ESC);
a direct current (DC) generator providing a pulsed DC bias signal to the bottom electrode over a plurality of cycles; and
a neutralization source that is external to the main plasma chamber, wherein the neutralization source is configured for providing a neutralization current into the main plasma chamber,
wherein the neutralization current is electrically coupled to the main plasma.

2. The system of claim 1,
wherein the main plasma chamber is configured as a capacitively coupled plasma (CCP) chamber.

3. The system of claim 1,
wherein the main plasma chamber is configured as an inductively coupled plasma (ICP) chamber.

4. The system of claim 1,
wherein the neutralization source includes an electron gun configured for generating electrons.

5. The system of claim 1,
wherein the neutralization source includes a secondary plasma chamber configured for generating a secondary plasma,
wherein the secondary plasma is more negatively charged than the main plasma.

6. The system of claim 5, further comprising:
a pump for pumping the secondary plasma into the main plasma chamber.

7. The system of claim 5,
wherein the main plasma is generated from a first gas mixture under a first process condition,
wherein the secondary plasma is generated from a second gas mixture under a second process condition.

8. The system of claim 1,
wherein the pulsed DC bias signal has an ON period and an OFF period in each cycle of the plurality of cycles,
wherein the neutralization current is continuously delivered into the main plasma during the ON period and the OFF period of each cycle of the plurality of cycles,
wherein the neutralization current is configured for neutralizing ions in a plurality of ions in the main plasma during the OFF period in the each cycle of the plurality of cycles.

9. A system, comprising:
a main plasma chamber configured for generating a main plasma, wherein the main plasma chamber includes a bottom electrode located within an electrostatic chuck (ESC);
a direct current (DC) generator providing a pulsed DC bias signal to the bottom electrode over a plurality of cycles, wherein the pulsed DC bias signal has an ON period and an OFF period in each cycle of the plurality of cycles; and
a secondary plasma chamber that is external to the main plasma chamber, wherein the secondary plasma chamber is configured for generating a secondary plasma that is more negatively charged than the main plasma;
a pump for delivering the secondary plasma into the main plasma chamber in order to provide a neutralization current that is electrically coupled to the main plasma.

10. The system of claim 9,
wherein the main plasma chamber is configured as a capacitively coupled plasma (CCP) chamber.

11. The system of claim 9,
wherein the main plasma chamber is configured as an inductively coupled plasma (ICP) chamber.

12. The system of claim 9,
wherein the main plasma is generated from a first gas mixture under a first process condition,
wherein the secondary plasma is generated from a second gas mixture under a second process condition.

13. The system of claim 9,
wherein the secondary plasma chamber is configured to continuously generate the secondary plasma such that the neutralization current is continuously delivered into the main plasma during the ON period and the OFF period of each cycle of the plurality of cycles,
wherein the neutralization current is configured for neutralizing ions in a plurality of ions in the main plasma during the OFF period in the each cycle of the plurality of cycles.

14. A method, comprising:
generating a main plasma in a main plasma chamber, wherein the main plasma chamber includes a bottom electrode located within an electrostatic chuck (ESC);
generating a pulsed DC bias signal that is delivered to the bottom electrode over a plurality of cycles; and
providing a neutralization current that is generated from a neutralization source that is external to the main plasma chamber,
wherein the neutralization current is electrically coupled to the main plasma.

15. The method of claim 14,
wherein the main plasma chamber is configured as a capacitively coupled plasma (CCP) chamber.

16. The method of claim 14,
wherein the main plasma chamber is configured as an inductively coupled plasma (ICP) chamber.

17. The method of claim 14,
wherein the neutralization source includes an electron gun configured for generating electrons,
the method further comprising pumping the electrons into the main plasma chamber.

18. The method of claim 14,
wherein the neutralization source includes a secondary plasma chamber configured for generating a secondary plasma,
wherein the secondary plasma is more negatively charged than the main plasma,
the method further comprising pumping the secondary plasma into the main plasma chamber.

19. The method of claim 18,
wherein the main plasma is generated from a first gas mixture under a first process condition,
wherein the secondary plasma is generated from a second gas mixture under a second process condition.

20. The method of claim 14,
wherein the pulsed DC bias signal has an ON period and an OFF period in each cycle of the plurality of cycles,
wherein neutralization current is continuously delivered into the main plasma during the ON period and the OFF period of each cycle of the plurality of cycles,
wherein the neutralization current is configured for neutralizing ions in a plurality of ions of the main plasma during the OFF period in the each cycle of the plurality of cycles.
